(19) United States
(12) Patent Application Publication
(10) Pub. No.: US 2008/0157227 A1
(43) Pub. Date: Jul. 3, 2008

(54) Semiconductor device and manufacturing process therefor

(75) Inventor: Kazutaka Manabe, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: ELPIDA MEMORY, INC., TOKYO (JP)

(21) Appl. No.: 12/003,174

(22) Filed: Dec. 20, 2007

(30) Foreign Application Priority Data
Dec. 27, 2006 (JP) 2006-351039

(51) Int. Cl. H01L 21/8234; H01L 27/088

(52) U.S. Cl. 257/401; 438/299; 257/E27.06; 257/E21.616

(57) ABSTRACT

An objective of the present invention is to provide a more miniaturized semiconductor device while maintaining low-resist contact.

A semiconductor device comprises transistors Tr1, Tr2, a first contact 13 and second contacts 10. The transistors Tr1, Tr2 are formed on a semiconductor substrate 1 and adjacent to each other. The first contact 13 is formed between the transistors Tr1, Tr2 in a self-alignment structure, connected to a common source to the transistors Tr1, Tr2 and contains a metal. The second contacts 10 are connected to the drains in the transistors Tr1, Tr2, respectively and contain a metal.

This application is based upon and claims the benefit of priority from Japanese patent application No. 2006-351039, filed on Dec. 27, 2006, the disclosure of which is incorporated herein in its entirety by reference.

### BACKGROUND OF THE INVENTION

1. Field of the Invention

The present invention relates to a semiconductor device, particularly a semiconductor device for miniaturization.

2. Description of the Related Art

Semiconductor device comprising an MOS (Metal-Oxide Semiconductor) transistor has been size-reduced. FIG. 1 is a cross-sectional view showing a configuration of a related semiconductor device. Here, there will be described an N type MOS transistor. An N type diffusion layer constituting a source/drain is disposed in a surface of a semiconductor substrate (p-well) 101. The N type diffusion layer comprises an N+ diffusion layer 102, a first N− diffusion layer 103 and a second N− diffusion layer 114. Here, the second N− diffusion layer 114 is means for reducing a contact resistance, and thus it may be omitted if a resistance is adversely affected. A gate insulating film 104 and a gate electrode 105 on the film 104 are disposed on the semiconductor substrate 101 such that they are sandwiched by the N type diffusion layers. There are sidewalls 107 on the sides of the gate insulating film 104 and the gate electrode 105. An interlayer insulating film 108 is formed such that it covers the gate insulating film 104, the sidewall 107 and the N type diffusion layer.

Within a contact hole 109 formed in the interlayer insulating film 108, there is formed a contact plug 110 for electrically connecting an interconnection 112 on the interlayer insulating film 108 and the N type diffusion layer.

Thus, in a related semiconductor device, a common contact (contact plug 110) has been used for either a source or a drain. Here, the contact plug 110 is generally a particulate (island) contact. In a particulate contact, as a semiconductor device is size-reduced, a contact size and thus a line width become smaller, leading to increase in a resistance. As a result, desired electric properties cannot be achieved, which makes miniaturization difficult.

For solving such a problem, it may be suggested to use a well-known self-alignment structure as miniaturization technique. Such an approach may be effective for miniaturization because a distance between the gates (the gate electrode 105 and the gate insulating film 104) becomes smaller. However, in this case, a range of the N+ diffusion layer 102 becomes so narrow that in the source/drain, an N− diffusion layer 103 having a relatively lower dopant concentration comes to be in contact with the contact plug 110. That is, when a metal plug is used as the contact plug 110, the N− diffusion layer 103 comes to be in contact with the metal. Consequently, a silicide layer formed in the contact area reaches the well, leading to a leak current between the source/drain and the well. As a method for avoiding the problem, it may be suggested to use a polysilicon plug in place of a metal plug. However, in such a case, a polysilicon plug has a higher resistance than a metal plug, so that electric properties of an MOS transistor may be deteriorated. In addition, for a CMOS, it is necessary to separately form an N type polysilicon plug and a P type polysilicon plug, resulting in more complex steps, which causes increase in a cost.

As a related technique, Japanese Laid-open Patent Publication No. 1998-242419 has disclosed a manufacturing process for a semiconductor device and a semiconductor device. The process for manufacturing a semiconductor device comprises the steps of forming a first insulating film on a main surface of a silicon semiconductor substrate; forming a first conducting layer on the first insulating film; forming a silicon oxide film on the first insulating layer; patterning the silicon oxide film and the first conducting layer to form a plurality of gate electrodes whose upper surfaces comprise an oxide film; introducing a dopant to a main surface of the semiconductor substrate between the gate electrodes to form a plurality of active regions; forming a silicon nitride film over the whole surface of the semiconductor substrate including the first insulating film and the gate electrode; forming a second insulating film on the silicon nitride film; forming an opening in the second insulating film between adjacent gate electrodes selected from the plurality of gate electrodes; and forming an opening in the silicon nitride film on the first insulating film and the first insulating film from the opening between the silicon nitride films in the respective sides of the adjacent gate electrodes to form a contact reaching the active region in the semiconductor substrate.

Japanese Laid-open Patent Publication No. 2001-44380 has disclosed a semiconductor device and a manufacturing process therefor. This semiconductor device comprises a capacitor over bit-line structure where an upper layer of a bit line comprises a capacitor. The semiconductor device comprises a lower insulating film covering a source/drain region connected to a capacitor; an upper insulating film formed over the lower insulating film; and a storage node contact penetrating the lower insulating film and the upper insulating film to the source/drain region. The source/drain region is substantially flat in the whole surface including the region where the storage node contact opens.

An exemplary objective of the present invention is to provide a more miniaturized semiconductor device and a manufacturing process therefor while maintaining a low resistance contact.

Another exemplary objective of the present invention is to provide a semiconductor device and a manufacturing process therefor capable of improving a transistor integration degree while reducing a cost.

### SUMMARY OF THE INVENTION

There will be described means for solving the above problems, using the reference numbers and the symbols used in the best mode for carrying out the invention. These reference numbers and symbols are given in parentheses to demonstrate relationship between the claims and the best mode for carrying out the invention, although these reference numbers and symbols should not be used for interpreting the technical scope of the invention defined in the claims.

For solving the above problems, an exemplary aspect of the present invention comprises two planar type transistors (Tr1, Tr2) comprising gate electrodes and sidewalls formed on a semiconductor substrate and a common source for the two transistors; a first contact (13) containing a metal between the sidewalls of the two transistors such that the first contact (13) is in contact with the sidewalls of the two transistors (Tr1, Tr2), which is electrically connected to the common source; and two second contacts (10) containing a metal, which are electrically connected to the respective drains for the two transistors.

An exemplary aspect of the present invention comprises two transistors (Tr1, Tr2), a first contact (13) and two second contacts (10). The two transistors (Tr1, Tr2) are adjacent to each other. The first contact (13) is formed between the sidewalls of the two transistors (Tr1, Tr2) in a self-alignment structure, connected to a common source to the two transistors (Tr1, Tr2) and contains a metal. The two second contacts (10) are connected to the drains in the two transistors (Tr1, Tr2), respectively and contain a metal.

In the present invention, the first contact (13) has a self-alignment structure. That is, the first contact (13) is formed such that the sidewalls are exposed between the two transistors in a self-alignment manner, so that a distance between the two transistors (Tr1, Tr2) can be reduced at low cost, resulting in more miniaturization of a semiconductor chip.

In the above semiconductor device, a distance between the end of the first contact (13) and the end of the gate electrode of the transistor (Tr1/Tr2) (for example, W₁ in FIG. 2) is preferably smaller than a distance between the end of the second contact (10) and the end of the gate electrode of the transistor (Tr1/Tr2) (for example, W₂ in FIG. 2). Since the first contact (13) comprises a self-alignment structure, the distance between the end of the first contact (13) and the end of the gate electrode can be smaller than the distance between the end of the second contact (10) and the end of the gate electrode. Thus, a semiconductor chip can be more miniaturized.

In the above semiconductor device, the first contact (13) preferably comprises at least one contact. Furthermore, each of the two second contacts (10) preferably comprises a plurality of contacts. A length in a gate width direction of the transistors (Tr1, Tr2) in at least one contact in the first contact is preferably equal to or longer than a length in a gate width direction in each of the plurality of contacts in the second contact. A length in a gate width direction of the first contact (13) (for example, the direction 15 in FIG. 3) is equal to or longer than that of each contact in the second contact (10). Thus, because of the self-alignment structure, a large contact area (a contact length L×a contact width W) can be maintained even when a contact width (W) between an N+ diffusion layer and the first contact (13) becomes smaller than that for the second contact (10) in a source, so that a contact resistance can be reduced while promoting integration.

In the above semiconductor device, the two transistors (Tr1, Tr2) are formed in the well surface of the semiconductor substrate (1). The source and the well preferably have an equal potential. Since the well (the semiconductor device 1) and the source have an equal potential, the problem of a leak current can be avoided in principle when the self-alignment structure of the first contact (13) causes contact between the N− diffusion layer and the first contact (13) in the source. Thus, a metal with a low resistance can be used as the contact plug 13. The term, “equal potential” means an equal potential in a degree that the problem of a leak current can be avoided, and can, therefore, include an error.

In the above semiconductor device, the first contact (13) preferably comprises a shape where a length in a gate width direction (for example, the direction 15 in FIG. 3) is longer than that in a gate length direction (for example, the direction 16 in FIG. 2). Thus, a large contact area (a contact length L×a contact width W) can be maintained, resulting in a reduced contact resistance. An exemplary shape is an ellipse having a longer axis in a gate width direction.

In the above semiconductor device, the first contact (13) preferably comprises a rectangular shape. Thus, a large contact area (a contact length L×a contact width W) can be more reliably maintained, resulting in a reduced contact resistance. The above semiconductor device preferably comprises one first contact (13).

To solve the above problems, an exemplary aspect of the present invention comprises the steps of (a) forming two planar type transistors (Tr1, Tr2) comprising gate electrodes and sidewalls on a semiconductor substrate (1) and a common source for the two transistors; (b) forming an interlayer insulating film (8) such that the interlayer insulating film (8) covers the semiconductor substrate (1) and the two transistors (Tr1, Tr2), and forming a first contact hole (11) in a self-alignment manner in a position corresponding to the common source in the interlayer insulating film (8) such that the sidewalls are exposed; (c) forming a first contact (13) such that a metal-containing substance fills the first contact hole (11); (d) forming two second contact holes (9) in positions corresponding to the respective drains of the two transistors (Tr1, Tr2) in the interlayer insulating film (8); and (e) forming two second contacts (10) such that a metal-containing substance fills the two second contact holes (9).

In the present invention, the first contact (13) is formed in a self-alignment manner, so that a distance between the two transistors (Tr1, Tr2) can be reduced in low cost and a semiconductor chip can be more miniaturized.

In the above process for manufacturing a semiconductor device, a distance between the end of the first contact (13) and the end of the gate electrode in the transistors (Tr1, Tr2) (for example, W₁ in FIG. 2) is preferably smaller than a distance between the end of the second contact (10) and the end of the gate electrode of the transistors (Tr1, Tr2) (for example, W₂ in FIG. 2). Since the first contact (13) comprises a self-alignment structure, the distance between the end of the first contact (13) and the end of the gate electrode can be smaller than the distance between the end of the second contact (10) and the end of the gate electrode. Thus, a semiconductor chip can be more miniaturized.

In the above process for manufacturing a semiconductor device, the first contact (13) preferably comprises at least one contact. Each of the two second contacts (10) preferably comprises a plurality of contacts. A transverse-sectional area of at least one contact is preferably larger than the sum of individual transverse-sectional areas of the plurality of contacts. Thus, even when the self-alignment structure makes a contact width (W) between an N+ diffusion layer and the first contact (13) smaller than that in the second contact (10) in a source, a large contact area (a contact length L×a contact width W) can be maintained, resulting in a reduced contact resistance while promoting integration.

In the above process for manufacturing a semiconductor device, it is preferable that steps (b) and (d) are simultaneously conducted and steps (c) and (e) are simultaneously conducted. Thus, the steps for forming the contact holes (11, 9) and the steps for forming the contacts (13, 10) can be combined to reduce a time for these steps and thus a cost.

According to the present invention, there can be provided a more miniaturized semiconductor device while maintaining contact with a low resistance.

### BRIEF DESCRIPTION OF THE DRAWINGS

FIG. 1 is a cross-sectional view showing a configuration of a related semiconductor device.

FIG. 2 is a cross-sectional view showing a configuration of an exemplary embodiment of a semiconductor device according to the present invention.

FIG. 3 is a plan view showing an exemplary embodiment of a semiconductor device according to the present invention.

FIG. 4 is a cross-sectional view showing an exemplary embodiment of a process for manufacturing a semiconductor device according to the present invention.

FIG. 5 is a cross-sectional view showing an exemplary embodiment of a process for manufacturing a semiconductor device according to the present invention.

FIG. 6 is a cross-sectional view showing an exemplary embodiment of a process for manufacturing a semiconductor device according to the present invention.

FIG. 7 is a cross-sectional view showing an exemplary embodiment of a process for manufacturing a semiconductor device according to the present invention.

### DETAILED DESCRIPTION OF PREFERRED EMBODIMENTS

There will be described embodiments of a semiconductor device of the present invention with reference to the appended drawings. The following description is related to a semiconductor device 20 comprising N type MOS transistors Tr1, Tr2, although the present invention can be similarly applied to a semiconductor device comprising P type MOS transistors by reversing a conductivity type. Furthermore, the present invention can be similarly applied to a semiconductor device comprising both N type and P type transistors.

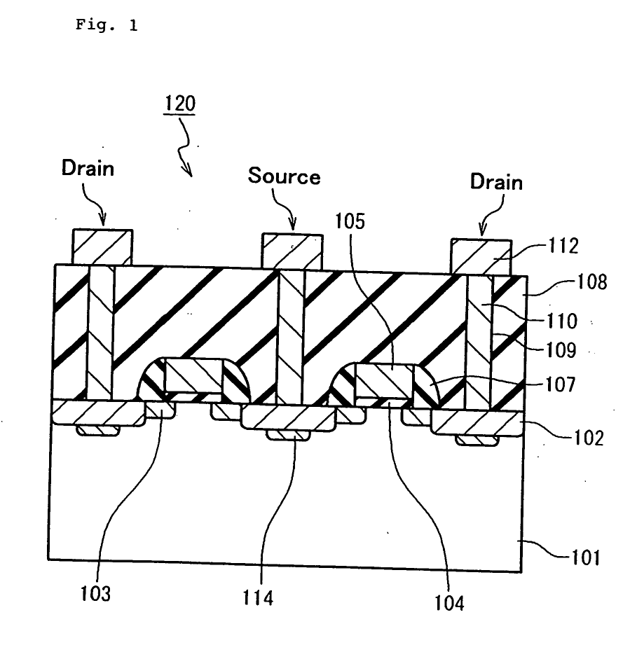

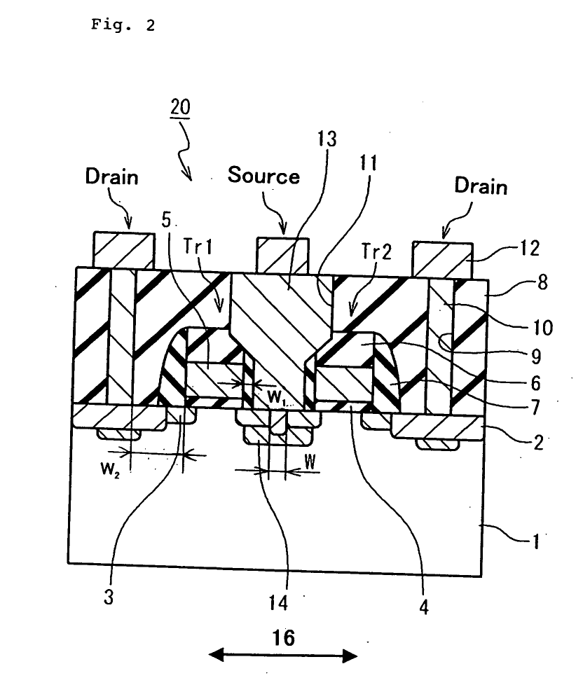

In FIGS. 1 to 7, 1 and 101 represent a semiconductor substrate (p-well), and 2 and 102 represent an N+ diffusion layer 3, and 103 represent a first N− diffusion layer, and 4 and 104 represent a gate insulating film. 5 and 105 represent a gate electrode, and 6 represents an on gate insulating film. 7 and 107 represent a sidewall, and 8 and 108 represent an interlayer insulating film. 9 and 109 represent a contact hole, and 10 and 110 represent a contact plug. 11 represents a contact hole, and 12 and 112 represent an interconnection. 13 represents a contact plug, and 14 and 114 represent a second N− diffusion layer. FIG. 2 is a cross-sectional view (longitudinal section) showing a configuration of an exemplary embodiment of a semiconductor device according to the present invention. A semiconductor device 20 comprises a semiconductor substrate 1, an N+ diffusion layer 2, a first N− diffusion layer 3, a second N− diffusion layer 14, a gate insulating film 4, a gate electrode 5, an on-gate insulating film 6, a sidewall 7, an interlayer insulating film 8, a contact hole 9, a contact plug 10, an interconnection 12, a contact hole 11, and a contact plug 13.

The semiconductor substrate 1 is a P type semiconductor substrate such as a boron-doped P-silicon substrate. However, it may be a P type well (p-well) formed by implanting a P type dopant such as boron into a semiconductor substrate surface.

The gate insulating film 4 and the gate electrode 5 constitute gates or MOS transistors Tr1, Tr2. The gate insulating film 4 is an insulating film formed on a channel region in the surface of the semiconductor substrate 1, such as a silicon oxide film.

The gate electrode 5 is an electrode formed on the gate insulating film 4, such as a phosphorous-doped polysilicon.

The on-gate insulating film 6 is formed in a self-alignment structure for preventing the gate electrode 5 from being electrically connected to the contact 13, and formed on the gate electrode 5. This on-gate insulating film 6 is an insulating film such as a silicon nitride film.

The sidewall 7 is an insulating film formed on the sides of the gate insulating film 4, the gate electrode 5 and the on-gate insulating film 6 for protecting them, such as a silicon nitride film.

The N+ diffusion layer 2, the first N− diffusion layer 3, and the second N− diffusion layer 14 are N type diffusion layers, which constitute a source /drain for the MOS transistors Tr1, Tr2. The first N− diffusion layer 3 is formed in both ends of the channel region in the surface of the semiconductor substrate 1. The N+ diffusion layer 2 is formed outside of the first N− diffusion layer 3 in relation to the channel region, and connected to one end of the contact plug 10. The second N− diffusion layer 14 is formed under the N+ diffusion layer 2. Herein, the second N− diffusion layer 14 is formed by ion implantation after forming the contact and is means for reducing a contact resistance, and therefore, the second N− diffusion layer 14 can be omitted as long as it does not adversely affect a contact resistance. Magnitude relation in a N type dopant concentration C of each N type diffusion layers is C (N+ diffusion layer 2)>C (first N− diffusion layer 3), C (N− diffusion layer 14).

The interlayer insulating film 8 is an insulating film formed covering the N+ diffusion layer 2, the sidewall 7 and the on-gate insulating film 6, such as a silicon oxide film having a low dielectric constant.

The contact hole 9 is a hole formed in the interlayer insulating film 8, which connects the N+ diffusion layer 2 as a drain for the MOS transistors Tr1, Tr2 with the interconnection 12. The contact plug 10 is an interconnection filling the contact hole 9, and electrically connects the N+ diffusion layer 2 as a drain for the MOS transistors Tr1, Tr2 with the interconnection 12. The contact plug 10 is a conductive material comprising a common (FIG. 1) contact structure, such as a metal film made of W (tungsten), Al (aluminum) or Cu (copper). The interconnection 12 sends or feeds signals related to the source/drain for the MOS transistors Tr1, Tr2.

The contact hole 11 is a hole formed in the interlayer insulating film 8, which connects the N+ diffusion layer 2 as a source for the MOS transistors Tr1, Tr2 with the interconnection 12. The lower part of the contact hole 11 is formed in a self-alignment manner by the on-gate insulating films 6 and the sidewalls 7 of the MOS transistors Tr1, Tr2. The contact plug 13 is an interconnection filling the contact hole 11, and connects the N+ diffusion layer 2 as a source for the MOS transistors Tr1, Tr2 with the interconnection 12 electrically. The contact plug 13 is a conductive material comprising a self-alignment structure, such as a metal film made of W (tungsten), Al (aluminum) or Cu (copper).

In the semiconductor device of this exemplary embodiment, the contact plug 13 between the MOS transistor Tr1 and the MOS transistor Tr2 is used as a self-alignment structure. By this self-alignment structure, the contact plug 13 is disposed between the two transistors such that it is in contact with the sidewalls. Thus, a distance between the MOS transistors Tr1 and Tr2 can be reduced in comparison with a semiconductor device comprising a common contact structure. Consequently, a semiconductor device can be miniaturized and highly integrated.

Furthermore, in the electric connection in the semiconductor device of this exemplary embodiment, the N type diffusion layer between the MOS transistor Tr1 and the MOS transistor Tr2 is a source while the N type diffusion layers in both sides are a drain. Here, the well (the semiconductor substrate 1) and the source have an equal potential. Therefore, by using the contact plug 13 as a self-alignment structure, the N− diffusion layer 3 is in contact with the contact plug 13 in the source while the problem of a leak current is avoided in principle. Thus, a metal having a low resistance can be used as a contact plug 13. An equal potential means an equal potential in a degree that the problem of a leak current can be avoided, and can, therefore, include an error.

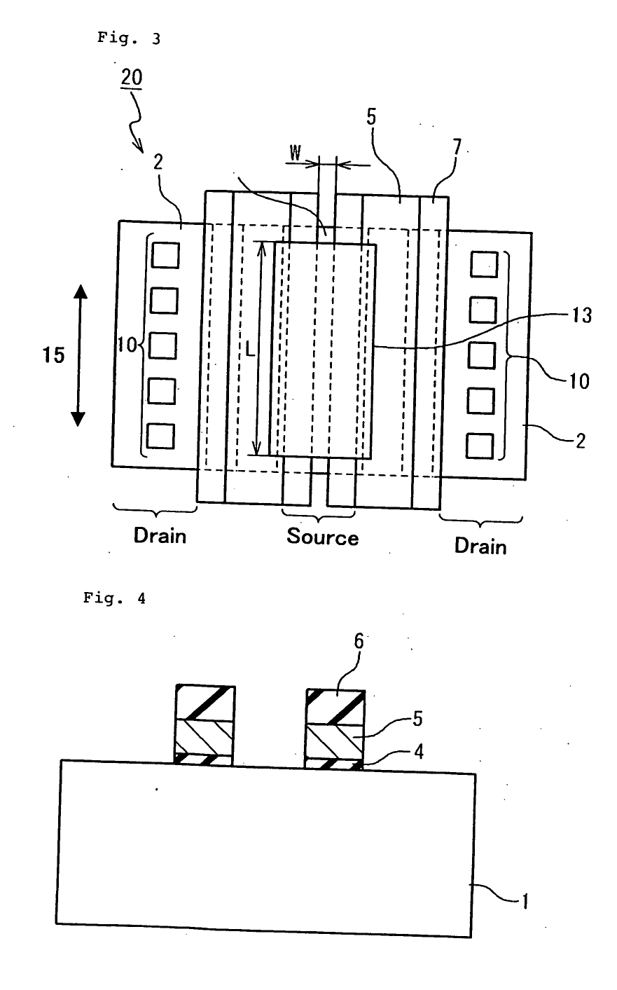

FIG. 3 is a plan view showing a configuration of an exemplary embodiment of a semiconductor device according to the present invention although the interconnection 12 and the interlayer insulating film 8 are not shown. The contact plug 10 as a drain is constituted by a particulate (island) plurality of plugs as in a related and common contact plug. In this contact plug 10, an area of a transverse-section (a plane parallel to the surface of the semiconductor substrate 1) is smaller in comparison with that in the contact plug 13. In this contact plug 10, the MOS transistors Tr1, Tr2 have a length in a gate width direction 15 equal to or shorter than that in the contact plug 13.

The contact plug 13 as a source is constituted by a small number of plugs, preferably one plug, in contrast to a related and common contact. This contact plug 13 has a larger transverse-sectional area larger in comparison with that in each plug in the contact plug 10. A length (L) of the MOS transistors Tr1, Tr2 in a gate width direction 15 is equal to or larger than that of each plug in the contact plug 10. Thus, even when the self-alignment structure makes a contact width (W) between the N+ diffusion layer 2 and the contact plug 13 smaller in comparison with the contact plug 10, the contact plug 13 can maintain a large contact area (a contact length L×a contact width W), resulting in a reduced contact resistance.

The contact plug 13 preferably comprises a transverse-sectional shape which is a slit (rectangle) longer in a gate width direction (the vertical direction in FIG. 3) 15. Thus, a large contact area (a contact length L×a contact width W) can be more reliably maintained. However, if an adequately low resistance can be maintained because, for example, an adequate contact length L can be ensured, its end or corner may be rounded or it may comprise an elliptical shape.

Like a common contact as shown in the figure, the contact plugs 10 in the drains in the sides are preferably particulate (island) rather than slit shaped. A slit shape is not advantageous because an opening width may be increased in the center of the slit as a lithography characteristic. The reason will be described. For the contact plug 13 (source), since junction leak is not problematic, a self-alignment structure can be employed and an increased opening width in the center is not significant. However, for a drain, it is necessary to prevent contacting of the first N− diffusion layer 3 with the contact plug 10 for avoiding junction leak. Therefore, a distance between the gate and the contact plug 10 must be increased or enlargement of the central opening must be prevented by special technique, which is not be suitable for miniaturization of a semiconductor chip or leads to a higher cost of a manufacturing process.

Thus, in the semiconductor device of the present invention, the contact plug (metal interconnection contact) in the source side comprises a slit shape and a self-alignment structure, while the contact plug (metal interconnection contact) in the drain side is a common particulate (island) contact. Thus, the problem of a leak current can be avoided, and while maintaining a low resistance contact (the use of a metal with a low resistance, and a low contact resistance), a distance between the transistors can be reduced to allow for a miniaturized and highly integrated semiconductor device.

Next, there will be described an exemplary embodiment of a process for manufacturing a semiconductor device of the present invention. FIGS. 4 to 7 are cross-sectional views showing an exemplary embodiment of a process for manufacturing a semiconductor device of the present invention.

As shown in FIG. 4, an isolation region (not shown) is formed in the surface of a semiconductor substrate by a common method. Next, boron is implanted to the surface of the semiconductor substrate to form a P type well. The semiconductor substrate 1 in this figure is the surface of the semiconductor substrate to which boron has been implanted. Subsequently, for example, the surface is oxidized to form a gate insulating film to a thickness of 5 nm, which covers the surface of the semiconductor substrate 1. Then, for example, a phosphorous-doped polysilicon with a thickness of 100 nm and a silicon nitride film with a thickness of 100 nm are deposited by CVD. Then, the phosphorous-doped polysilicon and the silicon nitride film are patterned into a desired pattern. During the process, part of the gate insulating film is also etched. As a result, a gate insulating film 4, a gate electrode 5 and an on-gate insulating film 6 are formed. FIG. 4 shows the state.

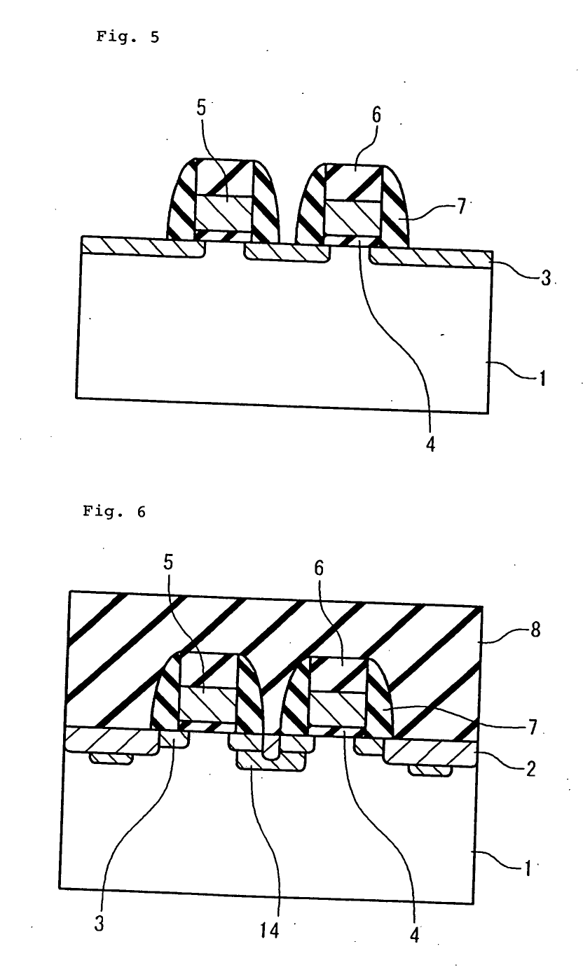

In the state of FIG. 4, then, using the on-gate insulating film 6 as a mask, arsenic is ion-implanted under, for example, the conditions of 10 keV and 5×10¹³ cm⁻², to form a first N− diffusion layer 3. Then, for example, a silicon nitride film with a thickness of 70 nm is deposited by CVD. Subsequently, the silicon nitride film is etched back by anisotropic etching back, to form a sidewall 7. FIG. 5 shows the state.

In the state of FIG. 5, then, using the on-gate insulating film 6 and the sidewall 7 as a mask, arsenic is ion-implanted under, for example, the conditions of 20 keV and 3×10¹⁵ cm⁻², to form an N+ diffusion layer 2. Next, for example, a silicon oxide film with a thickness of 1000 nm is deposited by CVD and the surface is, if necessary, flattened by, for example, CMP (Chemical Mechanical Polishing), and then the surface is covered by an interlayer insulating film 108. FIG. 6 shows this state.

In the state of FIG. 6, then, a contact hole 9 is opened at a position in the interlayer insulating film 8 corresponding to a drain for the MOS transistors Tr1, Tr2 by etching. Next, the contact hole 9 is buried with a contact plug 10 made of a metal material by CVD and CMP.

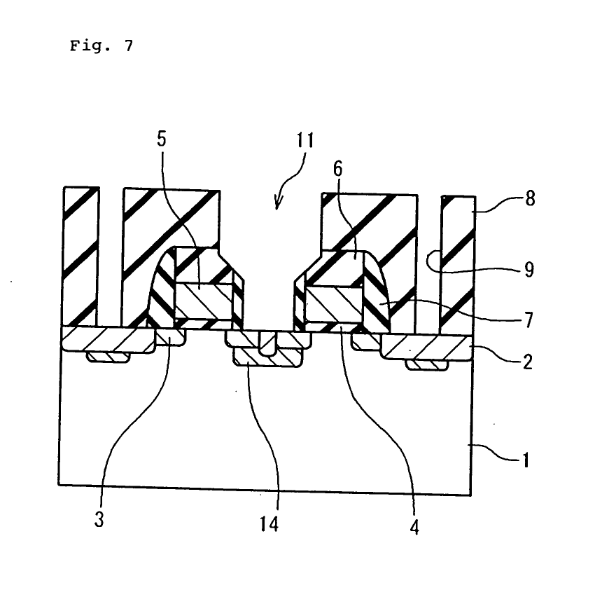

While opening the contact hole 9, a contact hole 11 is opened at a position in the interlayer insulating film 8 corresponding to the source by etching. During the process, anisotropic etching is conducted such that an etching rate is higher in the silicon oxide film than in the silicon nitride film, so that the shape of the lower part of the contact hole 11 is determined in a self-alignment manner by the shape of the on-gate insulating film 6 and the sidewall 7 in the MOS transistors Tr1, Tr2 from both sides. Then, while burying with the contact plug 10, the contact hole 11 is buried with a contact plug 13 made of a metal material by CVD and CMP. That is, the contact hole 11 and the contact plug 13 comprise a self-alignment structure. Furthermore, for example, phosphorous is ion-implanted under the conditions of 10 keV and 5×10¹³ cm⁻², to form a second N− diffusion layer 14. FIG. 7 shows the state.

In the state of FIG. 7, a film for an interconnection made of a metal material is deposited and then patterned to form an interconnection 12. Thus, a semiconductor device of the present invention shown in FIG. 1 can be manufactured.

In this exemplary embodiment, while forming the contact plug 11, the contact plug 13 can be formed with a metal in the same manner as the contact plug 11. Thus, for example, the number of manufacturing steps can be reduced, a time for the steps can be reduced and a cost can be reduced in comparison with the use of a polysilicon plug as a contact plug 13.

These embodiments are examples shown for a further understanding of the present invention and the present invention is not limited to these examples.

What is claimed is:

1. A semiconductor device, comprising
two planar type transistors comprising gate electrodes and sidewalls formed on a semiconductor substrate and a common source for the two transistors;
a first contact containing a metal between the sidewalls of the two transistors such that the first contact is in contact with the sidewalls of the two transistors, which is electrically connected to the common source; and
two second contacts containing a metal, which are electrically connected to the respective drains for the two transistors.

2. The semiconductor device as claimed in claim 1, wherein a distance between the end of the first contact and the end of the gate electrode of the transistor is smaller than a distance between the end of the second contact and the end of the gate electrode of the transistor.

3. The semiconductor device as claimed in claim 1, wherein
the first contact comprises at least one contact,
each of the two second contacts comprises a plurality of contacts,
a length in a gate width direction of the transistor in at least one contact in the first contact is equal to or longer than the length in the gate width direction of each of the plurality of contacts in the second contact.

4. The semiconductor device as claimed in claim 1, wherein
the two transistors are disposed in a well surface of the semiconductor substrate, and
the source and the well have a equal potential.

5. The semiconductor device as claimed in claim 1, wherein the first contact comprises a shape where a length in a gate width direction is longer than a length in a gate length direction.

6. The semiconductor device as claimed in claim 5, wherein the first contact comprises a rectangular shape.

7. The semiconductor device as claimed in claim 1, wherein the number of the first contact is one.

8. A process for manufacturing a semiconductor device comprising the steps of
(a) forming two planar type transistors comprising gate electrodes and sidewalls on a semiconductor substrate and a common source for the two transistors;
(b) forming an interlayer insulating film such that the interlayer insulating film covers the semiconductor substrate and the two transistors, and forming a first contact hole in a self-alignment manner in a position corresponding to the common source in the interlayer insulating film such that the sidewalls are exposed;
(c) forming a first contact such that a metal-containing substance fills the first contact hole;
(d) forming two second contact holes in positions corresponding to the respective drains of the two transistors in the interlayer insulating film; and
(e) forming two second contacts such that a metal-containing substance fills the two second contact holes.

9. The process for manufacturing a semiconductor device as claimed in claim 8, wherein a distance between the end of the first contact and the end of the gate electrode of the transistor is smaller than a distance between the end of the second contact and the end of the gate electrode of the transistor.

10. The process for manufacturing a semiconductor device as claimed in claim 8, wherein
the first contact comprises at least one contact,
each of the two second contacts comprises a plurality of contacts, and
a transverse-sectional area of the at least one contact is larger than the sum of transverse-sectional areas of the plurality of contacts.

11. The process for manufacturing a semiconductor device as claimed in claim 8, wherein
steps (b) and (d) are simultaneously conducted, and
steps (c) and (e) are simultaneously conducted.
